(19) United States
(12) Patent Application Publication
(10) Pub. No.: US 2013/0327392 A1
(43) Pub. Date: Dec. 12, 2013

(54) Chemically Linked Colloidal Crystals and Methods Related Thereto

(71) Applicant: California Institute of Technology, Pasadena, CA (US)

(72) Inventors: Raymond Weitekamp, Glendale, CA (US); Robert H. Grubbs, South Pasadena, CA (US); Harry A. Atwater, South Pasadena, CA (US)

(21) Appl. No.: 13/913,188

(22) Filed: Jun. 7, 2013

Related U.S. Application Data
(60) Provisional application No. 61/656,899, filed on Jun. 7, 2012.

(51) Int. Cl. H01L 31/0236; H01L 21/18

(52) U.S. Cl. CPC H01L 31/02363; H01L 21/18
USPC 136/256; 427/74; 156/249; 428/206; 438/57; 556/405

(57) ABSTRACT

Nanoparticles may be formed into colloidal crystals that are chemically linked to a substrate. In certain implementations, the nanoparticles are formed into a colloidal crystal on an initial substrate, and then brought into contact with a binding precursor capable of chemically linking the colloidal crystal to a final substrate. Reacting the binding precursor to chemically link the colloidal crystal to the final substrate chemically links the colloidal crystal to the final substrate via functional groups linked to the nanoparticles and the final substrate respectively.

### CROSS-REFERENCE TO RELATED APPLICATIONS

This application claims the benefit of U.S. Provisional Application No. 61/656,899, filed Jun. 7, 2012, which is incorporated by reference herein.

### FEDERAL SUPPORT STATEMENT

The U.S. Government has certain rights in this invention pursuant to Grant No. DE-SC0001293 awarded by the Department of Energy.

### TECHNICAL FIELD

The compositions, systems, and methods described herein relate to colloidal crystals. More specifically, the compositions, systems, and methods relate to a plurality of nanoparticles arranged in a contiguous, periodic array and chemically linked to a substrate or to form a single network.

### BACKGROUND

Colloidal crystals are ordered arrays of nanoparticles. If the nanoparticles have a different refractive index than their surrounding medium, the colloidal crystal provides an ordered variation in refractive index. Colloidal crystals can thereby offer an optical band gap analogous to the electronic band gap in semiconductors. But while colloidal crystals can be fabricated using self-assembly, the deposition of a well-ordered layer of nanoparticles over a large surface area has proved challenging. The challenge is compounded when a surface needs to be coated with the well-ordered layer to form a robust coating while maintaining compatibility with common processing techniques such as acid etching.

### SUMMARY

Thus, there exists a need in the art for chemically linking colloidal crystals to substrates or linking particles of a colloidal crystal together to form a robust network. The crystals and methods described herein provide robust colloidal crystals suitable for practical applications.

In certain aspects, the colloidal crystals and methods described herein provide a colloidal crystal chemically linked to a substrate bearing a first plurality of functional groups. A plurality of nanoparticles bearing a second plurality of functional groups are arranged in a contiguous, periodic array, and are chemically linked to the substrate via the first and the second plurality of functional groups. The chemical linkage may be a direct bond (herein, a “link,” which may be an ionic bond, a covalent bond, or a coordinate covalent bond) or a series of intervening atoms (herein, a “linker,” the atoms of which may be joined through covalent bonds, ionic bonds, coordinate covalent bonds and/or other associative interactions (such as an inclusion complex)). In some implementations, there may be a link between a functional group of the first plurality and a functional group of the second plurality. In some implementations, a functional group of the first plurality may be linked to a functional group of the second plurality through a linker, which may comprise a coordination complex or other suitable chemical linkage.

In some implementations, one or more chemical links or linkers between the contiguous, periodic array of nanoparticles and the substrate have at least one tunable physical property. In such implementations, a tunable physical property may be a density, a length, an average displacement between two terminal atoms on the linkers, a change in the average number of kinks in the linkers, an orientation, a dielectric tensor, a refractive index, or some other suitable physical property. In such implementations, a tunable physical property may vary with temperature, strain, applied magnetic field, applied electric field, or may otherwise vary based on its environment.

In some implementations, a functional group of the first plurality may be chemically linked to a polymer matrix. In some such implementations, the polymer matrix may be an adhesion layer. In some implementations where a functional group of the first plurality is linked to a polymer matrix, the polymer matrix may be the substrate.

In some implementations, the nanoparticles may be disposed as a monolayer. In some implementations, the plurality of nanoparticles may be silica nanoparticles, zirconia nanoparticles, metal oxide nanoparticles (e.g., titania nanoparticles), or other suitable nanoparticles.

In some implementations, the substrate may be coated with a layer of brush polymers bearing the first plurality of functional groups. In some such implementations, the plurality of nanoparticles may be covalently bonded to the substrate through backbone bonding to the brush polymers. In some implementations in which the substrate is coated with a layer of brush polymers, the brush polymers may have tunable anisotropic dielectric constants.

In some implementations, the first plurality of functional groups may be lithographically patterned on the substrate.

In some implementations, the substrate may be an optoelectronic device, which may include a solar cell or an optical sensor. In some implementations, the substrate may be a waveguide.

In some implementations, at least one of the first and the second plurality of functional groups may include phosphonates, silanes, amines, alcohols, organometallates (e.g., organozirconium), or other suitable functional groups.

In certain aspects, a colloidal crystal is chemically linked to a substrate by forming the colloidal crystal on an initial substrate and contacting the colloidal crystal with a binding precursor capable of chemically linking the colloidal crystal to a final substrate. The binding precursor may be reacted to chemically link the colloidal crystal to the final substrate, in some implementations creating a polymer matrix. In some implementations, the initial substrate may be the final substrate. In some implementations, the colloidal crystal formed on the initial substrate may be reversibly attached to a stamp and transferred to the final substrate before being detached from the stamp.

In some implementations, one or more chemical links or linkers between the colloidal crystal and the final substrate have at least one tunable physical property, e.g., a density, a length, an average displacement between two terminal atoms on the linkers, a change in the average number of kinks in the linkers, an orientation, a dielectric tensor, a refractive index, or some other suitable physical property. In such implementations, a tunable physical property may vary with temperature, strain, applied magnetic field, applied electric field, or may otherwise vary based on its environment.

The colloidal crystal formed on the initial substrate may comprise silica nanoparticles, zirconia nanoparticles, metal oxide nanoparticles such as titania nanoparticles, or some other suitable nanoparticles. In some implementations, the colloidal crystal formed on the initial substrate may be a monolayer. In some implementations, the colloidal crystal may be patterned on the initial substrate.

In some implementations, the binding precursor may include an aldehyde. In some implementations, the binding precursor may include poly(vinyl alcohol).

In some implementations, the final substrate is a solar cell.

In certain aspects, the colloidal crystals and methods described herein provide a chemically linked, two-dimensional colloidal crystal, comprising a plurality of nanoparticles arranged in a two-dimensional, contiguous, periodic array, each nanoparticle bearing a plurality of functional groups. In such colloidal crystals, each nanoparticle in the plurality of nanoparticles is chemically linked to at least one other nanoparticle in the plurality of nanoparticles via the plurality of functional groups, such that the periodic array of nanoparticles is chemically linked to form a single network. The chemical linkage via the plurality of functional groups may comprise a link between a first functional group and a second functional group, a link between a first functional group and a coordination complex linked to a second functional group, a link between a first functional group and a linker chemically linked to a second functional group, or some other suitable chemical linkage. In some implementations, the network may be embedded in a polymer matrix.

In some implementations of the chemically linked, two-dimensional colloidal crystal, the single network has at least one tunable physical property, e.g., a density, a length, an average displacement between two terminal atoms on the linkers, a change in the average number of kinks in the linkers, an orientation, a dielectric tensor, a refractive index, or another suitable physical property. In such implementations, a tunable physical property may vary with temperature, strain, applied magnetic field, applied electric field, or may otherwise vary based on its environment.

In some implementations of the chemically linked, two-dimensional colloidal crystal, the plurality of nanoparticles may be silica nanoparticles, zirconia nanoparticles, metal oxide nanoparticles (e.g., titania nanoparticles), or other suitable nanoparticles.

In some implementations of the chemically linked, two-dimensional colloidal crystal, the plurality of functional groups may include phosphonates, silanes, amines, alcohols, organometallates (e.g., organozirconium), or other suitable functional groups.

### BRIEF DESCRIPTION OF THE DRAWINGS

The crystals and methods described herein are set forth in the appended claims. However, for the purpose of explanation, several embodiments are set forth in the following drawings.

FIG. 1 is a diagram of a chemically linked colloidal crystal, according to an illustrative implementation;

FIG. 2 is a diagram of a chemically linked colloidal crystal, according to an illustrative implementation;

FIG. 3 is a diagram of a nanoparticle chemically linked to the backbone of a polymer brush, according to an illustrative implementation;

FIG. 4 is a diagram of a nanoparticle chemically linked to the terminus of a polymer brush, according to an illustrative implementation;

FIG. 5 is a diagram of a chemically linked colloidal crystal, according to an illustrative implementation;

FIG. 6 is a block diagram of a patterned colloidal crystal chemically linked to a substrate, according to an illustrative implementation; and

FIG. 7 is a flow chart of a process for chemically linking a colloidal crystal to a substrate, according to an illustrative implementation.

### DETAILED DESCRIPTION

In the following description, numerous details are set forth for the purpose of explanation. However, one of ordinary skill in the art will realize that the implementations described herein may be practiced without the use of these specific details and that the implementations described herein may be modified, supplemented, or otherwise altered without departing from the scope of the compositions, systems, and methods described herein.

The compositions, systems, and methods described herein relate to chemically linked colloidal crystals. A nanoparticle in the colloidal crystal (or a plurality of nanoparticles, or even all of the nanoparticles in the colloidal crystal) may be chemically linked to a substrate via a first plurality of functional groups borne on the nanoparticle and a second plurality of functional groups borne on the substrate. The chemical linkage may be a link (which may be an ionic bond, a covalent bond, or a coordinate covalent bond) or a linker (the atoms of which may be joined through covalent bonds, ionic bonds, coordinate covalent bonds and/or other associative interactions (such as an inclusion complex)). Such a nanoparticle may also or alternatively be chemically linked to at least one other nanoparticle in the colloidal crystal via a plurality of functional groups borne on the first and the second nanoparticle respectively. A chemically linked array of nanoparticles may form a single network, whether the nanoparticles are chemically linked directly with each other or where one or more of the nanoparticles are chemically linked to a single substrate and not all nanoparticles are chemically linked directly with each other.

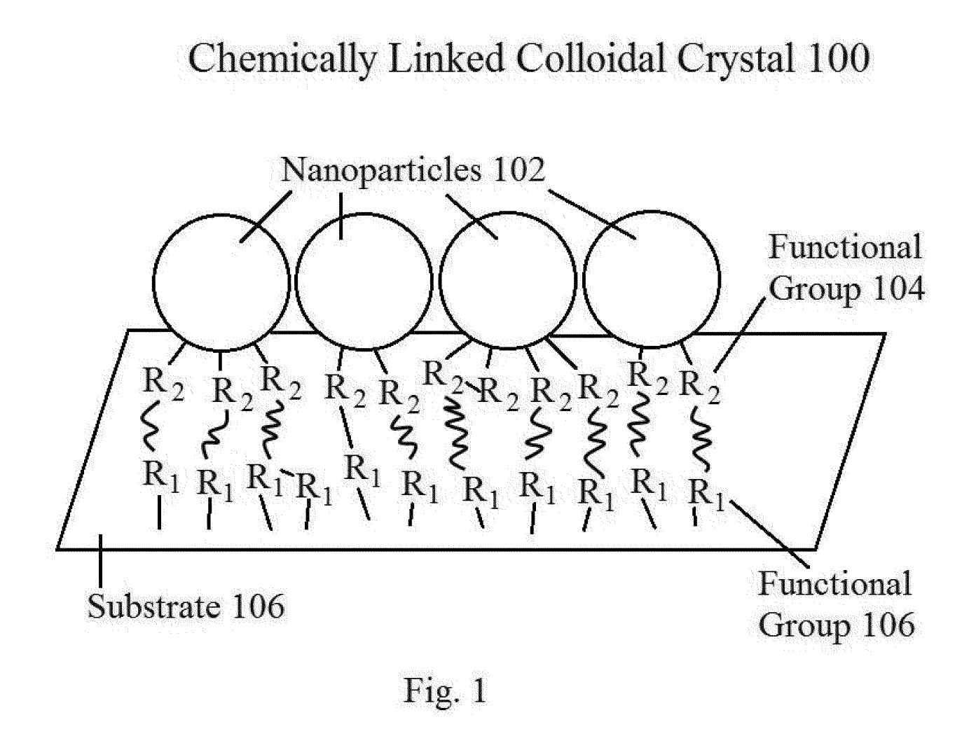

FIG. 1 is an illustrative diagram of a chemically linked colloidal crystal 100. Colloidal crystal 100 comprises a plurality of nanoparticles 102 bearing a plurality of functional groups 104. As depicted, nanoparticles 102 are chemically linked to a substrate 106 bearing a plurality of functional groups 108 via functional groups 104 and functional groups 108. In some implementations, there may not be a substrate 106, in which case each nanoparticle 102 is chemically linked to at least one other nanoparticle 102 via functional groups 104 such that nanoparticles 102 are chemically linked to form a single network. In such implementations, the nanoparticles may be arranged in a two-dimensional, contiguous, periodic array.

Nanoparticle 102 is a particle sized on a scale of approximately 1-1000 nm. As depicted, nanoparticles 102 are spherical and uniformly sized, but in some implementations one or more nanoparticles 102 may be different in one or more of shape and size. Similarly, nanoparticles 102 are depicted as being disposed as a monolayer, but other arrangements are possible and contemplated by the present disclosure. A nanoparticle 102 may be composed of organic materials, inorganic materials, or a combination of both. Illustrative examples of nanoparticle materials include polymers such as polystyrene, silica, zirconia, and metal oxides such as titania. In some implementations, one or more nanoparticles 102 may be quantum dots, such as lead sulfide quantum dots. In some implementations, some nanoparticles 102 are composed of different materials than other nanoparticles 102. In some implementations, the composition of the nanoparticles may be varied to generate photocleavable, photodegradable, or chemically etchable domains within the colloidal crystal. In some implementations, one or more nanoparticles 102 may be quantum dots.

Functional groups 104 may chemically link a nanoparticle 102 to other nanoparticles 102 or to substrate 106. Such a chemical link may consist of a direct bond with a second nanoparticle 102, with substrate 106, with a second functional group 104, or with a functional group 108. Alternatively, functional group 104 may chemically link a nanoparticle to other nanoparticles 102 or to substrate 106 via a coordination complex, a linker, a polymer matrix, or some other suitable intermediary. Functional groups 104 may include phosphonates, silanes, siloxanes, amines, carboxylic acids, sulfonic acids, olefins, alcohols, aldehydes, epoxides, thiols, azides, alkynes, organometallates (illustrative examples of which include organozirconium, organoaluminum, and organotin), or other suitable functional groups. In some implementations, a nanoparticle 102 may be linked to more than one type of functional group 104. In some implementations, different nanoparticles 102 may be associated with different functional groups 104, e.g., such that discrete sets of nanoparticles 102 can be manipulated independently of other sets under defined conditions.

Substrate 106 is a surface bearing functional groups 108. Substrate 106 may be composed of a polymer matrix, silica, or another suitable material, and may be flexible, stretchable, deformable, and/or rigid. In some implementations, substrate 106 may be a waveguide, an optoelectronic device such as an optical sensor or a solar cell, or some other device. In some implementations, a surface of substrate 106 may be patterned to template a desired colloidal crystal structure.

A functional group 108 may chemically link substrate 106 to a nanoparticle 102. Such a chemical link may consist of a direct bond with a nanoparticle 102 or with a functional group 104. Alternatively, functional group 108 may provide the chemical link via an intervening series of atoms, e.g., through a coordination complex, a linker, a polymer matrix, or some other suitable intermediary. Functional groups 108 may include phosphonates, silanes, siloxanes, amines, carboxylic acids, sulfonic acids, olefins, alcohols, aldehydes, epoxides, thiols, azides, alkynes, organometallates (illustrative examples of which include organozirconium, organoaluminum, and organotin), or other suitable functional groups. In some implementations, substrate 106 may be linked to more than one type of functional group 108. In some implementations, one or more types of functional groups 108 may be patterned on substrate 106. In such implementations, patterning may be accomplished through lithography, self-assembly, or another suitable method, and may be used to template a desired colloidal crystal structure. As an illustrative example of such an implementation, if substrate 106 will not bond with functional groups 104 without the intermediary of a functional group 108, creating a striped pattern of regions bearing functional group 108 on substrate 106 may give rise to a correspondingly striped pattern of colloidal crystal chemically linked to substrate 106. Such patterning may be used with several varieties of functional group 108 and 104 to allow selective binding of a first set of nanoparticles 102 to one region of substrate 106 and a second set of nanoparticles 102 to a second region of substrate 106.

As depicted, colloidal crystal 100 comprises a plurality of nanoparticles 102 arranged in a contiguous, periodic array and chemically linked to substrate 106 via a plurality of functional groups 104 and a plurality of functional groups 108. In some implementations, one or more chemical linkages between one or more of nanoparticles 102, functional groups 104, substrate 106, and functional groups 106 may have a tunable physical property. In such implementations, the tunable physical property may vary with temperature, strain, applied magnetic field, pH, applied electric field, or may otherwise vary based on its environment. In such implementations, a tunable physical property may be a density, a dielectric tensor, a refractive index, or another suitable physical property. As an illustrative example of such an implementation, if the density of chemical linkers between substrate 106 and nanoparticles 102 varies with temperature (e.g., through a change in the average displacement between two terminal atoms on the chemical linkers or through other changes in the average number of kinks in the linkers) while the density of chemical linkers between nanoparticles 102 does not, a change in temperature may change the distance between nanoparticles 102 and substrate 106 but not the distance between nanoparticles 102. In some implementations, colloidal crystal 100 may be a chemical sensor, e.g., as described in Lee et al., J. Am. Chem. Soc. 2000, 122, 9534-9537 and Holtz et al., Nature 1997, 389, 829-832, which are incorporated herein in entirety by reference. In some implementations, a functional group 104 may be chemically linked to a polymer matrix, which may be substrate 106 or may be an adhesion layer linking nanoparticles 102 to substrate 106.

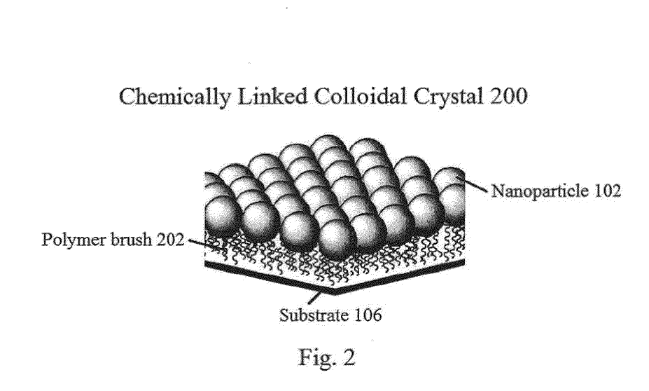

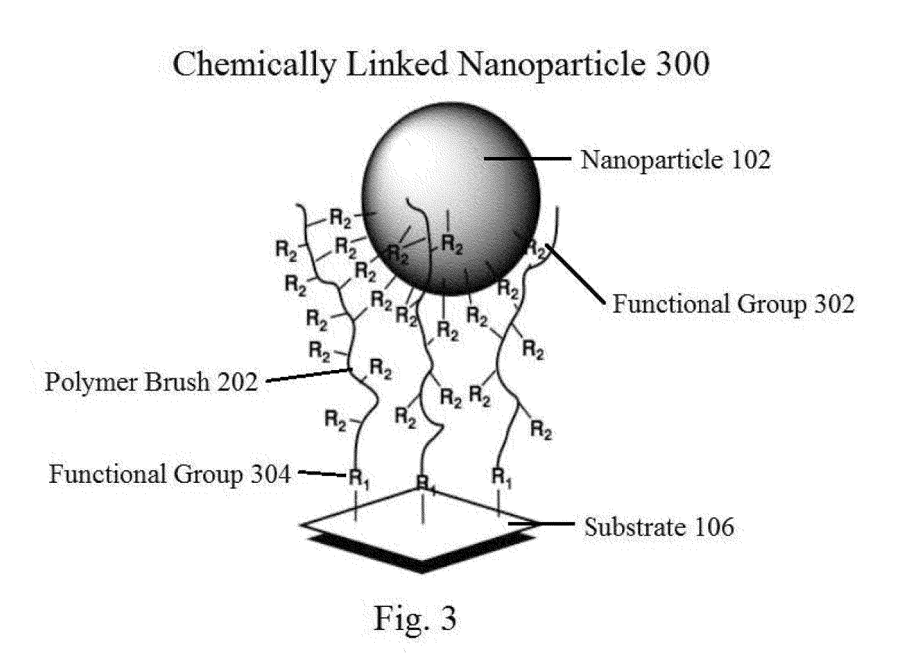

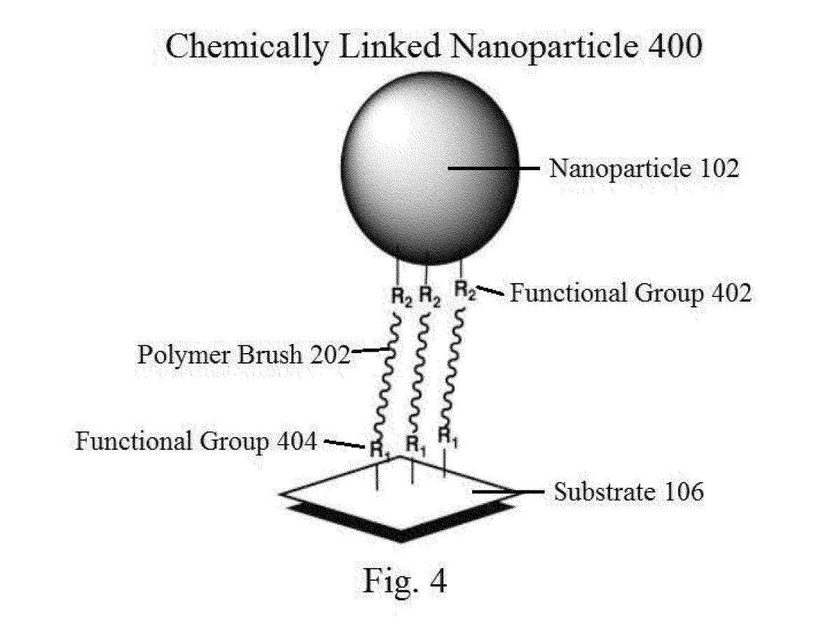

FIG. 2 is an illustrative diagram of a chemically linked colloidal crystal 200. Referring to FIG. 1, colloidal crystal 200 is an implementation of colloidal crystal 100, but omits certain elements of colloidal crystal 100 for clarity. As depicted, nanoparticles 102 are chemically linked to substrate 106 via polymer brushes 202. As described in detail in relation to FIGS. 3 and 4, a polymer brush 202 is a carbon chain that is chemically linked to at least one functional group 104 and at least one functional group 108. In some implementations, a functional group 104 or a functional group 108 may be a photoisomerizable functional group, e.g., azobenzene or spiropyran.

Polymer brushes 202 may be generated on substrate 106, e.g., via a surface-initiated living polymerization, which may be a ring-opening metathesis polymerization or an atom transfer radical polymerization. Illustrative examples of such surface-initiated living polymerizations are described in: Juang et al., Langmuir 2001, 17, 1321-1323; Lerum et al., Langmuir 2011, 27, 5403-5409; and Wu et al., Langmuir 2009, 25, 2900-2906, which are incorporated herein in entirety by reference. Polymer brushes 202 may include poly(N-isopropylacrylamide), as described in Kaholek et al., Chem. Mater. 2004, 16, 3688-3696, which is incorporated herein in entirety by reference. In some implementations, polymer brushes 202 may be patterned to generate templates for nanoparticles 102. In such implementations, polymer brushes 202 may be patterned lithographically, through self-assembly techniques, or through some other suitable method. Polymer brushes 202 may have a tunable, anisotropic dielectric constant. In some implementations, polymer brushes 202 may change conformation in response to stimuli, which may include changes in electric field, magnetic field, pH, temperature, solute concentration, or other suitable stimulus. In some implementations, polymer brushes 202 may selectively adsorb other molecules, such as volatile organic compounds. Such adsorption may induce conformational changes that provide a detectable signal or a measurable change in a physical property, allowing the polymer brushes to be used to detect, measure, or even quantify such adsorbable molecules.

FIG. 3 is an illustrative diagram of a chemically linked nanoparticle 300. Referring to FIG. 2, chemically linked nanoparticle 300 represents a close view of a possible implementation of colloidal crystal 200. As depicted, nanoparticle 102 is chemically linked to the backbone of a polymer brush 202 via functional groups 302, and polymer brush 202 is linked to surface 106 via a functional group 304. As polymer brush 202 conforms to the topology of nanoparticle 102, polymer brush 202 may form multiple bonds to nanoparticle 102. In some implementations, polymer brush 202 may also form multiple bonds to substrate 106.

FIG. 4 is an illustrative diagram of a chemically linked nanoparticle 400. Referring to FIG. 2, chemically linked nanoparticle 400 represents a close view of a possible implementation of colloidal crystal 200. As depicted, nanoparticle 102 is chemically linked to the backbone of a polymer brush 202 via a single functional group 402, and polymer brush 202 is linked to surface 106 via a single functional group 404. In the absence of other differences between chemically linked nanoparticles 300 and 400, the chemical link between nanoparticle 102 and surface 106 in chemically linked nanoparticle 400 may be mechanically weaker and more sensitive to environmental changes than that in chemically linked nanoparticle 300. Thus, a user may choose to create a more robust or more sensitive array, as may be desirable in a particular application, or may create a composition or system featuring both varieties of polymer brush 202 to allow selective manipulation of different nanoparticles or sets of nanoparticles.

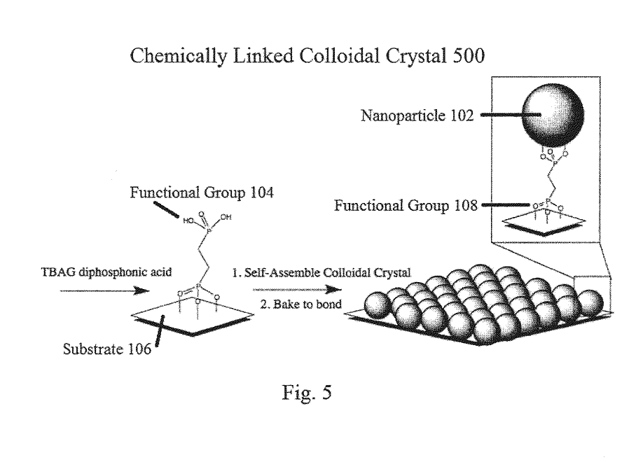

FIG. 5 is an illustrative diagram of a chemically linked colloidal crystal 500. Referring to FIG. 1, colloidal crystal 500 is an implementation of colloidal crystal 100. As depicted, a monolayer of silica nanoparticles 102 is chemically linked to a silica substrate 106 via phosphonate functional groups 104 and 108. The chemically linked colloidal crystal depicted may be created by generating a self-assembled monolayer of a disphosphonic acid (SAMP) on substrate 106 using the tethering by aggregation and growth (T-BAG) method described in E. L. Hanson et al., J. Am. Chem. Soc. 126, 10510-10511 (2004). Nanoparticles 102 may then be deposited in a contiguous, periodic array on top of the SAMP layer using T-BAG, Langmuir-Blodgett, electric-field-induced assembly, convective assembly, or controlled evaporation methods. Once the colloidal crystal is formed on the surface, nanoparticles 102 may be bound to the SAMP layer by baking at 150° C. for 48 hours. As the SAMP is a monolayer, the bound nanoparticles 102 also form a monolayer, and any further layers of a colloidal crystal may be washed away.

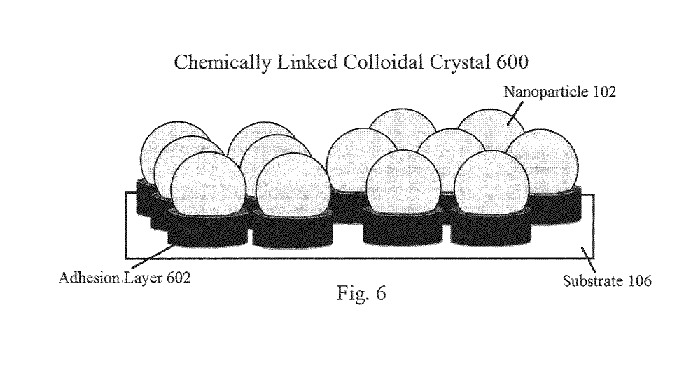

FIG. 6 is an illustrative diagram of a chemically linked colloidal crystal 600. Referring to FIG. 1, colloidal crystal 600 is an implementation of colloidal crystal 100, but omits certain elements of colloidal crystal 100 for clarity. As depicted, nanoparticles 102 are chemically linked to substrate 106 via an adhesion layer 602. Adhesion layer 602 is chemically linked to substrate 106, and is patterned to create a template for colloidal crystal self assembly. The user-defined pattern of adhesion layer 602 may generate a colloidal crystal 600 with a substantially user-selected arrangement of nanoparticles. The pattern may be generated functionally, topologically, or in some other suitable fashion. Functional patterning generates a pattern of functional groups with a chemical affinity for select nanoparticles 102 or functional groups 104, while topological patterning generates larger binding surfaces in the adhesion layer 602.

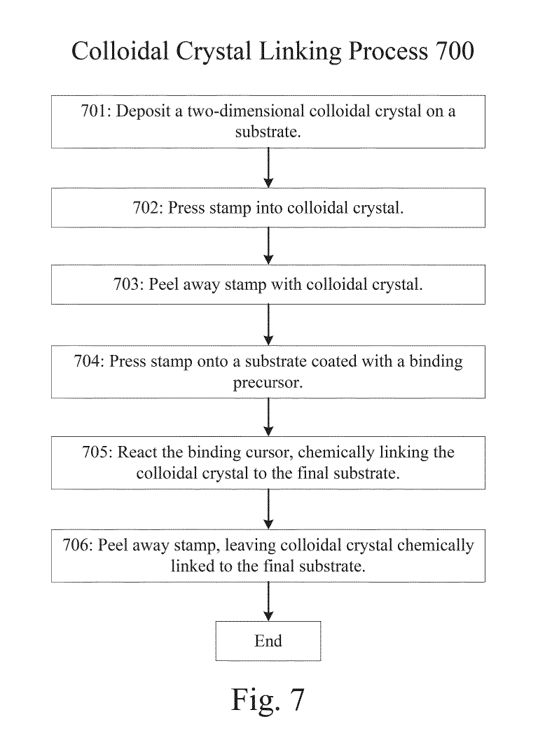

FIG. 7 is an illustrative flow chart of colloidal crystal linking process 700. Colloidal crystal linking process 700 chemically links a colloidal crystal to a substrate, and may be used to produce a chemically linked colloidal crystal like described in relation to FIG. 1. Colloidal crystal linking process 700 begins with step 701, in which a two-dimensional colloidal crystal is formed on an initial substrate. The colloidal crystal may be formed using the Langmuir-Blodgett method, the T-BAG method, electric-field-induced assembly, convective assembly, controlled evaporation, or any other suitable method for forming a colloidal crystal. Referring to FIG. 1, the two-dimensional colloidal crystal may be an array of nanoparticles 102, and the initial substrate may be a substrate 106, although the two need not be chemically linked via functional groups 104 and 108.

In step 702, a stamp is pressed into the colloidal crystal of step 701. The stamp may be composed of poly(dimethylsiloxane) (PDMS) or some other suitable material to which the colloidal crystal may be reversibly attached. In step 703, as the stamp is peeled away from the initial substrate, the colloidal crystal adheres to the stamp's stamping surface and is separated from the initial substrate. In some implementations, the detachment of the colloidal crystal from the initial substrate can be promoted by applying a chemical (e.g., to cleave a link or linker), an electric field, or another suitable stimulus. Similarly, in some implementations, the colloidal crystal may be reversibly attached to and detached from the stamp by applying an electric field or some other suitable stimulus.

In step 704, the stamp is pressed onto a final substrate coated with a binding precursor, thereby contacting the colloidal crystal with a binding precursor. The binding precursor includes a collection of moieties that can form the chemical linkage between the colloidal crystal and the final substrate in whole or in part. In some implementations, the collection of moieties may be bound to the final substrate when the final substrate is coated with the binding precursor, e.g., as are the polymer brushes 202 described in relation to FIG. 2. In other implementations, the collection of moieties may be independent molecules capable of binding both the substrate and the colloidal crystal. In some implementations, the initial substrate of colloidal crystal linking process 700 may also serve as the final substrate of colloidal crystal linking process 700. In step 705, the binding precursor chemically reacts with the colloidal crystal (e.g., via its functional groups) to create the chemical linkage between the colloidal crystal and the final substrate. The reaction may occur spontaneously, or may be triggered by exposure to high temperature (e.g., baking), exposure to ultraviolet radiation, a chemical initiator or catalyst, or another suitable stimulus. Once the reaction is complete, the stamp may be peeled away in step 706, leaving the colloidal crystal chemically linked to the final substrate and ending colloidal crystal linking process 700.

As an illustrative example of colloidal crystal linking process 700, silica spheres of a nominal 700 nm diameter (Polysciences Inc.) were functionalized with an aminopropyl silane and deposited in a two-dimensional colloidal crystal on a glass slide using the Langmuir-Blodgett method. Poly(vinyl alcohol) (PVA, average molecular weight of 10,000 g/mol, 88% hydrolyzed, Sigma-Aldrich) was spun-cast from an aqueous solution containing 1% PVA by weight and 5% gluteraldehyde by weight onto the top glass surface of solar cells. PDMS stamps were prepared from Sylgard 184 (1:10 curing agent:elastomer base, Dow Corning) by pouring the solution into petri dishes to a thickness of ˜5 mm and heated at 80° C. for 85 minutes. The colloidal crystal was transferred to the PDMS stamp by firmly pressing the stamp into the colloidal crystal and peeling it away gently. The stamp was then pressed against the PVA-coated surface of the solar cell by hand, and the cells and stamp were purged with argon, baked heated at 100° C. for one hour, purged with argon again, and heated at 100° C. for a further hour. The cells were allowed to cool to room temperature, and the PDMS stamps were peeled away, leaving the colloidal crystals bound to the PVA-coated solar cell.

In some implementations, colloidal crystal linking process 700 may be performed without a stamp. In such implementations, the colloidal crystal is contacted with a binding precursor without being lifted from the initial substrate. As an illustrative example, a two-dimensional colloidal crystal composed of 700 nm diameter aminated silica spheres was formed on a glass slide by Langmuir-Blodgett deposition, as above. An aqueous solution of 50% gluteraldehyde by weight (Sigma-Aldrich) was introduced to the colloidal crystal surface, and the sample was heated on a hot plate at 70° C. for twenty minutes. The sample was washed with methanol and acetone, and then dried. In contrast with a similar colloidal crystal that had not been exposed to a crosslinking agent, the sample could not be removed by a PDMS stamp.

While various embodiments of the present disclosure have been shown and described herein, it will be obvious to those skilled in the art that such embodiments are provided by way of example only. Numerous variations, changes, and substitutions will now occur to those skilled in the art without departing from the disclosure. Examples include binding nanoparticles together via chemical linkages that develop between the nanoparticles at an air/liquid interface; embedding colloidal crystals in another material, such as a polymer; and employing the 2D colloidal crystals described herein as photonic crystals, antireflective coatings, growth initiators, or nanopattern templates. It should be understood that various alternatives to the embodiments of the disclosure described herein may be employed in practicing the disclosure. Elements of an implementation of the crystals and methods described herein may be independently implemented or combined with other implementations. It is intended that the following claims define the scope of the disclosure and that methods and structures within the scope of these claims and their equivalents be covered thereby.

1. A chemically linked colloidal crystal, comprising:
a substrate bearing a first plurality of functional groups; and
a plurality of nanoparticles bearing a second plurality of functional groups,
wherein the plurality of nanoparticles are arranged in a contiguous, periodic array and are chemically linked to the substrate via the first and the second plurality of functional groups.

2. The colloidal crystal of claim 1, wherein a functional group of the first plurality is chemically linked to a polymer matrix.

3. The colloidal crystal of claim 2, wherein the polymer matrix is an adhesion layer.

4. The colloidal crystal of claim 1, wherein the nanoparticles are disposed as a monolayer.

5. The colloidal crystal of claim 1, wherein the substrate is coated with a layer of brush polymers bearing the first plurality of functional groups.

6. The colloidal crystal of claim 5, wherein the plurality of nanoparticles are covalently bonded to the substrate through backbone bonding to the brush polymers.

7. The colloidal crystal of claim 5, wherein the brush polymers have tunable anisotropic dielectric constants.

8. The colloidal crystal of claim 1, wherein the plurality of nanoparticles are silica nanoparticles.

9. The colloidal crystal of claim 1, wherein the substrate is a solar cell.

10. A method of chemically linking a colloidal crystal to a substrate, comprising:
forming a colloidal crystal on an initial substrate;
contacting the colloidal crystal with a binding precursor capable of chemically linking the colloidal crystal to a final substrate; and
reacting the binding precursor to chemically link the colloidal crystal to the final substrate.

11. The method of claim 10, wherein the initial substrate is the final substrate.

12. The method of claim 10, further comprising:
reversibly attaching the colloidal crystal to a stamp;
transferring the colloidal crystal to the final substrate; and
detaching the stamp from the colloidal crystal.

13. The method of claim 10, wherein reacting the binding precursor creates a polymer matrix.

14. The method of claim 10, wherein the colloidal crystal is patterned on the initial substrate.

15. The method of claim 10, wherein the colloidal crystal comprises silica nanoparticles.

16. The method of claim 10, wherein the final substrate is a solar cell.

17. A chemically linked, two-dimensional colloidal crystal, comprising:
a plurality of nanoparticles arranged in a two-dimensional, contiguous, periodic array, each nanoparticle bearing a plurality of functional groups,
wherein each nanoparticle in the plurality of nanoparticles is chemically linked to at least one other nanoparticle in the plurality of nanoparticles via the plurality of functional groups, such that the periodic array of nanoparticles is chemically linked to form a single network.

18. The colloidal crystal of claim 17, wherein a first functional group of the plurality is chemically linked to a linker that is chemically linked to a second functional group of the plurality.

19. The colloidal crystal of claim 17, wherein the single network has at least one tunable optical property.

20. The colloidal crystal of claim 19, wherein the at least one tunable physical property is strain-dependent.
